(19) United States
(12) Patent Application Publication
(10) Pub. No.: US 2007/0115635 A1
(43) Pub. Date: May 24, 2007

(54) Passive cooling for fiber to the premise (FTTP) electronics

(76) Inventors: Andrew G. Low, Southlake, TX (US); Thyagarajan Ramachandran, Arlington, TX (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 11/282,941

(22) Filed: Nov. 18, 2005

(51) Int. Cl. H05K 7/20

(52) U.S. Cl. 361/700; 361/704; 165/104.33

(57) ABSTRACT

A phase change material, including multiple phase change materials of different formulations, is placed in heat transfer association with an electronics enclosure (e.g., a sealed enclosure) deployed in an environment that causes the electronics and the phase change material to experience periods of heating and periods of cooling. During the periods of heating, the phase change material absorbs heat and changes at least partially from a first state to a second state to maintain the temperature of the electronics at a desirable level. During the periods of cooling, the phase change material reverts at least partially back to the first state for future heat absorption. The phase change material is cooled by a thermally cooler body such as the night sky. The electronics enclosure and phase change material may be placed in a second enclosure covered with a paint having a paint additive that reflects solar radiation.

### BACKGROUND OF THE INVENTION

Electronics generate significant amounts of heat, which may be compounded by external thermal loading such as in situations where the electronics are operating within enclosures subject to solar loading. The electronics may be equipped with heat sinks to cool the electronics under such operating conditions. This approach is inadequate for electronics supporting higher data rate architectures (e.g., Very high speed Digital Subscriber Line (VDSL)), which increase the heat generated by the electronics.

Traditionally, mechanical fans directing airflow across electronics have been used for the electronics that generate greater amounts of heat when the heat sinks do not suffice. However, fans have several disadvantages. First and foremost, fans require maintenance. In some cases, the electronics include additional software processes to detect and provide an alarm signal for fan failure. When a fan fails, the electronics may have to be shut down until the fan can be serviced or replaced. Second, fans have power requirements that must be met to enable them to rotate. Finally, fans generate audible noise which is often undesirable in a residential neighborhood. Because of at least these three example disadvantages, customers and equipment manufacturers desire a cost-effective passive cooling system (i.e., a system that does not use fans or any other active cooling method).

### SUMMARY OF THE INVENTION

In one embodiment of the present invention, a phase change material is placed within an electronics enclosure in heat transfer association with a location defined for the electronics. The electronics enclosure is adapted to be deployed in an environment that causes the electronics and the phase change material to experience periods of heating and periods of cooling. During the periods of heating, the phase change material absorbs heat and changes at least partially from a first state to a second state to maintain the temperature of the electronics at a desirable level. During the periods of cooling, the phase change material reverts at least partially back to the first state for future heat absorption.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1A is a network block diagram of an optical network architecture in which an embodiment of the present invention may be employed;

FIG. 1B is a network block diagram of another optical network architecture in which an embodiment of the present invention may be employed;

FIG. 2A is a perspective view of an Optical Network Unit (ONU) in its operating environment;

FIG. 2B is a perspective view of an Optical Network Terminal (ONT) in its operating environment;

FIG. 3 is a cross-sectional perspective view of an ONU embodiment having a Phase Change Material (PCM) disposed therein;

FIG. 4 is a perspective view of a PCM in contact with an ONU roof;

FIG. 5 is a cross-sectional perspective view of an ONU embodiment having a PCM disposed therein;

FIG. 6 is a cross-sectional view of an ONU embodiment having multiple PCMs;

FIG. 7 is a cross-sectional view of an ONU embodiment having multiple PCMs of different formulations;

FIG. 8 is a cross-sectional view of an ONU embodiment having a thermal buffer;

FIG. 9 is a perspective view of an ONU embodiment that is coated with a reflective paint;

FIG. 10 is a block diagram of an embodiment including both active and passive cooling systems; and

FIG. 11 is a flow chart illustrating a process of manufacturing an ONU according to an embodiment of the present invention.

### DETAILED DESCRIPTION OF THE INVENTION

A description of preferred embodiments of the invention follows.

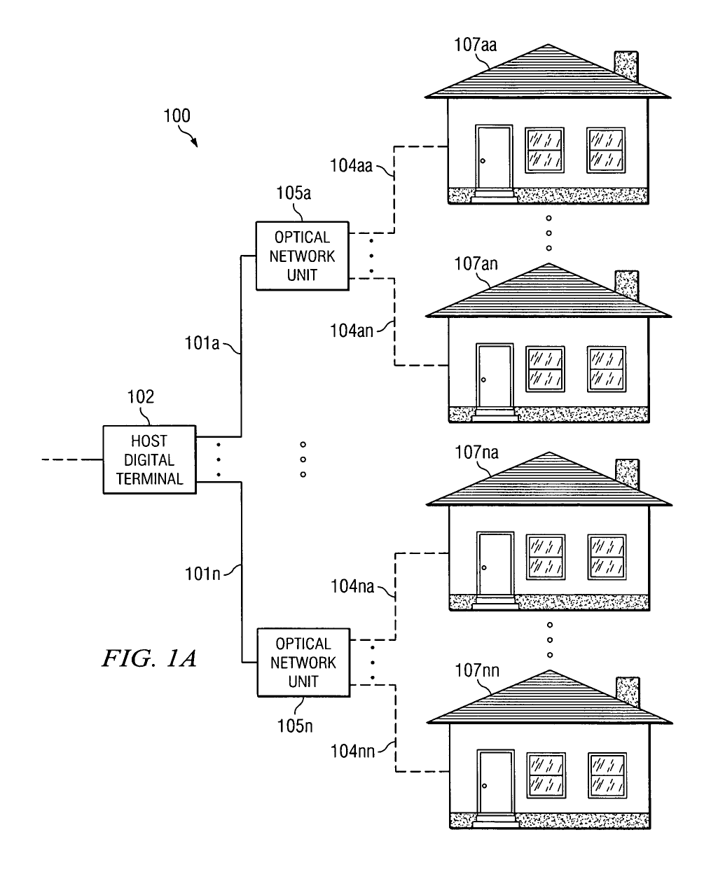

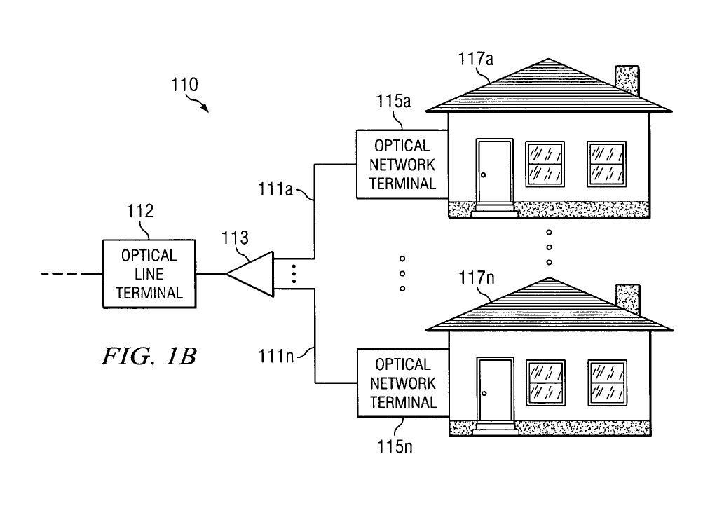

FIG. 1A is an example optical network architecture 100 referred to as a Fiber To The Curb (FTTC) architecture in which an embodiment of the present invention may be employed. A Host Digital Terminal (HDT) 102 communicates via optical fiber links 101a-101n with multiple Optical Network Units (ONUs) 105a-105n. The ONUs 105a-105n in turn communicate via copper links 104aa-104nn (e.g., twisted pair) with subscribers 107aa-107nn.

FIG. 1B is another example optical network architecture 110 referred to as the Fiber To The Premise (FTTP) architecture (e.g., Fiber To The Business (FTTB) or Fiber To The Home (FTTH)) in which an embodiment of the present invention may be employed. An Optical Line Terminal (OLT) 112 communicates via an optical splitter 113 and optical fiber links 111a-111n with Optical Network Terminals (ONTs) 115a-115n associated with subscribers 117a-117n. The OLT 112 and HDT 102 may be connected to or in communication with any number of media sources, including a video server, data network, or Public Switched Telephone Network (PSTN).

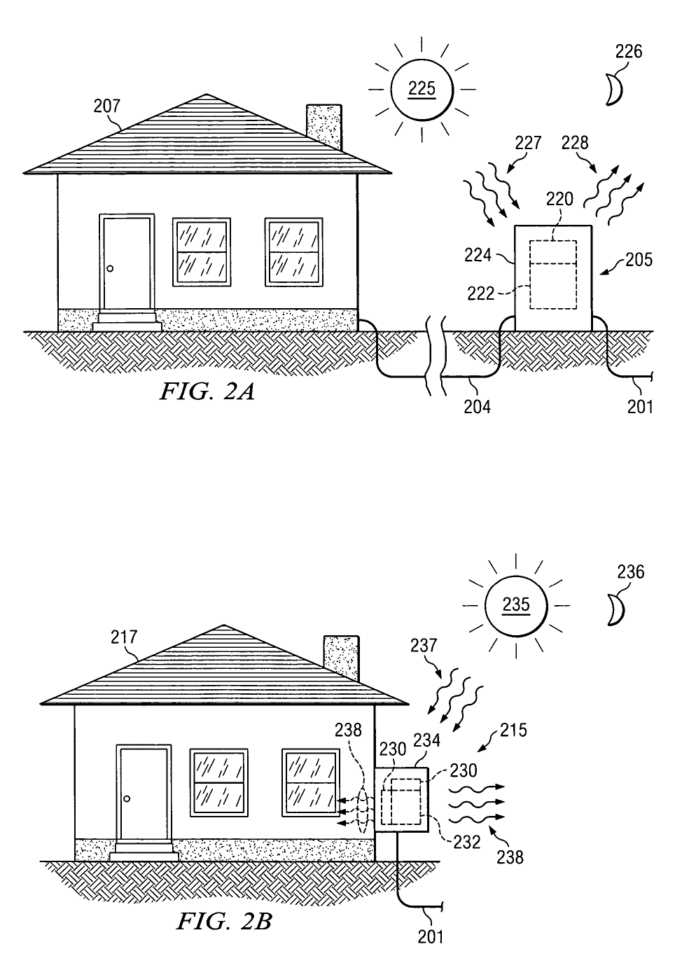

FIG. 2A shows an outdoor environment in which an ONU of an FTTC architecture 100 operates. A subscriber 207 communicates with an ONU 205 via a copper line 204, such as a twisted pair wire. The ONU 205 includes an electronics enclosure 222 containing electronics (not shown), that may (1) convert optical signals (not shown) being carried along an optical fiber line 201 to electrical signals (not shown) carried along the copper line 204 and (2) multiplex the electrical signals or de-multiplex the optical signals. The electronics enclosure 222 may be a sealed enclosure to protect the electronics from flooding or other weather conditions unsuitable for electronics. The electronics enclosure 222 may be sealed hermetically, for example, with a rubber gasket.

The electronics within the electronics enclosure 222 may produce up to 23 Watts of heat at data rates supported by Asymmetric Digital Subscriber Lines (ADSL) (about 1.5 Mbit/s), and presently used sealed enclosures may be designed to dissipate the 23 watts of heat. With the deployment of Internet Protocol Television (IPTV), however, data rates increase up to 100 Mbit/s, and, as a result, the electronics produce between 38 and 46 Watts of heat. Such heat produced by the electronics, when converted into temperature increase, in combination with solar heat, which increases the temperature of the air in the electronics enclosure by up to 10° C., may exceed the heat dissipation capacity of the sealed enclosures, which in turn may exceed a temperature rating of components (e.g., 55° C. or 85° C.). Thus, a cooling system that can keep the electronics cool while under solar loading can be employed to keep the electronics within their temperature ratings (e.g., 55° C. or 85° C.).

Active cooling systems, especially fans, have been traditionally used to cool electronics that produce increased amounts of heat due to higher data rate architectures. Network service providers, however, do not want active cooling systems because active cooling systems make noise, increase costs, require maintenance, may require changes to the network equipment software to include an alarm signal to indicate when a fan fails, require power, generate heat (e.g., 1 Watt), require copper wiring, and may require voltage conversions. Equipment manufacturers, like network service providers, do not want expensive cooling solutions.

A phase change material is a material that changes isothermally in physical state when heated. For example, the material may change from a first state to a second state, such as from a solid to a liquid, from a liquid to a gas, or from one solid phase to another solid phase. When heat is removed from the liquid or gas, e.g., heat transfer to a thermally cooler body, the material reverts from the second state back to the first state (e.g., from a liquid to a solid phase).

According to an embodiment of the present invention shown in FIG. 2A, a phase change material 220 may be placed between an external side of the top of the electronics enclosure 222 and an internal side of the top of a second enclosure 224. In one embodiment, the phase change material completely changes states. In other embodiments, the phase change material at least partially changes states.

According to an embodiment of the present invention, a phase change material 220 may be placed on top of the electronics enclosure 222 to absorb solar loading influencing temperature rise in the electronics enclosure 222. So long as sufficient phase change material 220 is available to absorb the heat generated by the electronics and solar loading, the phase change material 220 is able to passively cool the electronics enclosure 222 and helps to maintain the electronics below maximum operating temperature while under maximum solar loading.

During non-solar loading conditions, such as when an ONU is exposed to a cloudless night sky, the phase change material 220 and other materials of the ONU can radiate up to 33 Watts, which helps the phase change material to revert from its second state back to its first state, as described above.

The phase change material 220 is preferably chosen or formulated to meet environmental conditions in which the ONU or ONT is deployed. Various materials may be used as phase change materials. For example, certain alcohols may be used as a liquid phase change material. Alcohol changes from a liquid to a vapor in a heated state. Alcohol phase change materials have been used in heat pipes, but these are only used for constant temperature, constant cooling conditions. Moreover, the volume of alcohol expands greatly when it changes from a liquid to a vapor. Thus, a phase change material with a smaller coefficient of expansion is preferable for many applications, such as ONU, ONT, or other electronics enclosures passive cooling applications.

Example other phase change materials include hydrated salts (vinegar salt), paraffin wax, or fatty acids. Hydrated salt requires a significant amount of heat to change it from a solid to a liquid and thus has the greatest heat capacitance among these materials.

For electronics rated at 85° C. and depending on the temperature ranges or solar loading at a given geographical location, the phase change material may be formulated to change phase at a temperature between 29° C. and 48° C. A phase change material that changes phase below 48° C. may be too low to allow the phase change material to resolidify during times of non-solar loading. A material having a phase change temperature greater than 48° C. maybe too high to effectively maintain the temperature within the electronics enclosure 222 below about 75° C., for example.

According to one embodiment, a hydrated salt is contained in a package such as a metalized pouch (e.g., a silver-coated plastic bag) (not shown). The hydrated salt may be mixed with additives (e.g., stabilizers) to increase a number of thermal cycles over which the phase change material effectively provides its cooling capacity. Some metalized pouches of PCM can be made to last through 10,000 cycles, which is enough to outlast the usefulness of the electronics they keep cool. Certain additives may provide for 10,000 cycles and maintain the phase change temperature within ±3° C. Such phase change material can provide about 170-200 watts of heat absorption spread over a 10 hour day, depending on the volume of the phase change material.

The metallic pouch having the hydrated salt mixture may be placed on top of or inside the electronics enclosure in thermal association with the electronics or solar loading region of the electronics enclosure to create a “cool sink” for the heat being produced by the electronics or introduced by the solar load. An example hydrated salt mixture can absorb approximately 170 watt-hours in a 1″×12″×12″ volume. Therefore, when the solar load adds heat to the electronics during the daytime, the hydrated salt in the metalized pouch (i.e., phase change materials) can maintain the temperature inside the electronics enclosure within an acceptable range. Referring again to FIG. 2A, at night, represented by a moon 226, when the sun's radiation 227 no longer places a solar load on the electronics enclosure 222, the liquid hydrated salt radiates its stored potential energy to the evening sky or otherwise cooler air on the outside of the electronics enclosure in the form of dissipated heat 228 and thus reverts from its liquid state back to its solid state. In some embodiments, the heat stored in the PCM 220 radiates through the second enclosure 224 to the night clear sky (i.e., space), which maintains a temperature of −40° C.

A wire mesh of honeycomb may be added to the phase change material package to provide evenly distributed thermal conduction within the PCM, which may result in better cooling or heating properties for the electronics enclosure, especially if the phase change material package is thick. In other words, a wire honeycomb structure inside of the phase change material package allows the center of the phase change material in a solid state, for example, to melt into a liquid state. In this way, the phase change material absorbs and dissipates heat more efficiently.

FIG. 2B shows the environment in which an optical network terminal (ONT) of a fiber to the premise (FTTP) architecture 110 operates. In one embodiment, an ONT 215 is attached to a sidewall of a subscriber's home 217. In this embodiment, a phase change material package 220 is placed on top of the electronics enclosure 232 and also between the electronics enclosure 232 and the sidewall of the subscriber's home 217. During daytime hours, represented by a sun 235, the sun's radiation 237 adds solar loading to the electronics enclosure 232. The phase change material 230 absorbs the heat produced by electronics (not shown) because of operation of the electronics and the solar loading. During nighttime hours, represented by a moon 236, the phase change material 230 radiates 238 heat to at least one of the following: a cool wall of the subscriber's home 217 or business, the sky due to the night sky effect, or cool air surrounding the ONT. The phase change material may be cooled by radiating its potential energy (i.e., stored temperature) to other thermally cooler bodies as well.

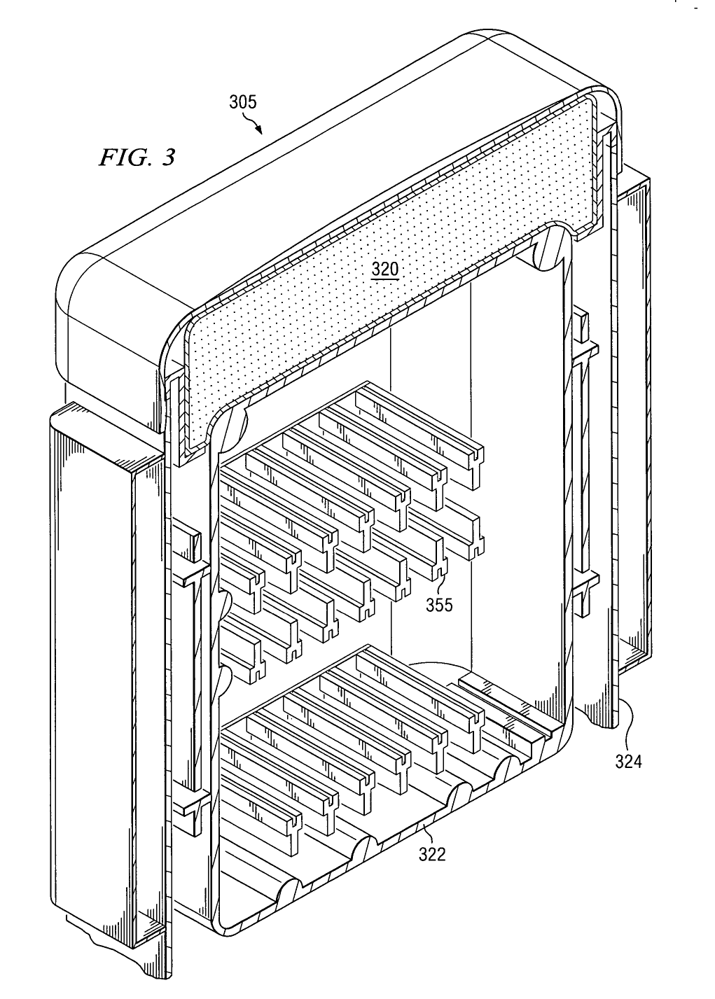

FIG. 3 is a perspective cross-sectional view of an ONU 305. The ONU 305 includes an electronics enclosure 322 having guides 355 in which to insert electronics (not shown). The electronics enclosure 322 may be housed within a second enclosure 324, which may be a pedestal. The ONU 305 may also house a fiber splice box in a sealed enclosure (not shown), a terminal block (not shown), or a protector block (not shown). A phase change material pouch 320, such as the phase change material package 220 of FIG. 2A in the form of a pouch, may be positioned to contact the top exterior surface of the electronics enclosure 322 and the top interior surface of a second enclosure 324.

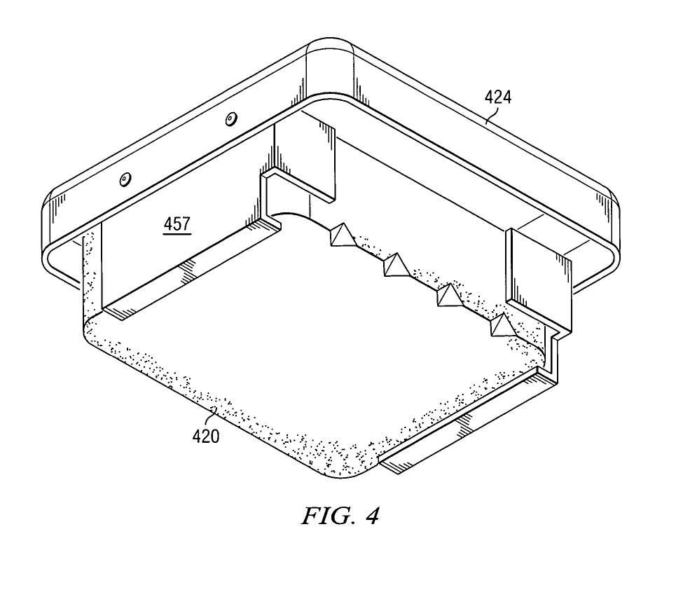

FIG. 4 illustrates how a phase change material package 420 may be positioned relative to the roof or top of the pedestal 424 using brackets 457.

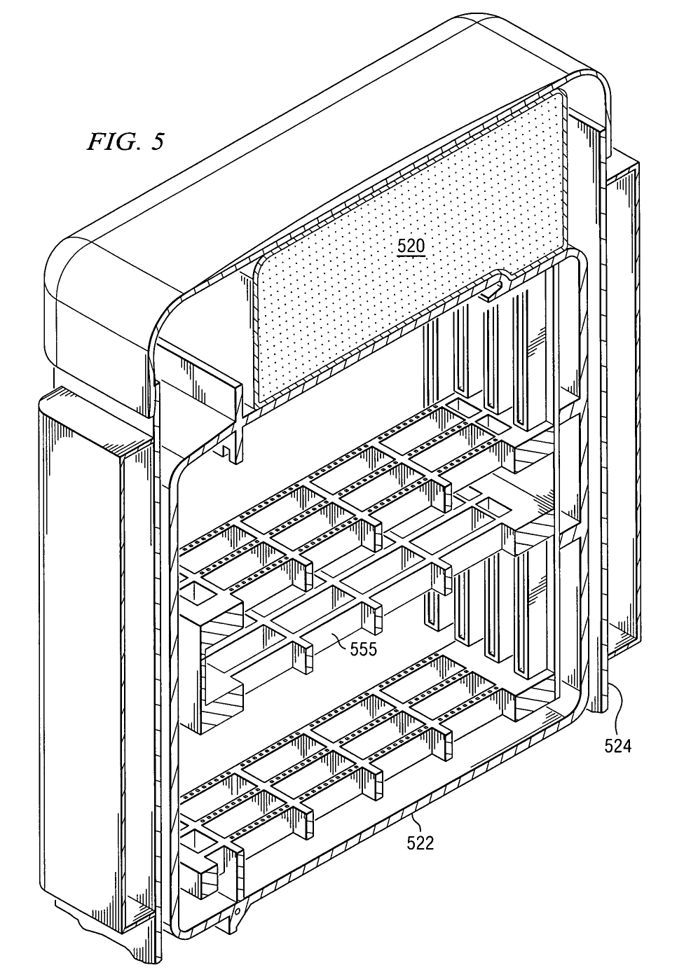

FIG. 5 is another embodiment in which a phase change material package 520 makes contact with a portion of the interior surface of an electronics enclosure 522 and the interior surface of the pedestal 524 roof. The electronics may be supported by a card cage assembly 555.

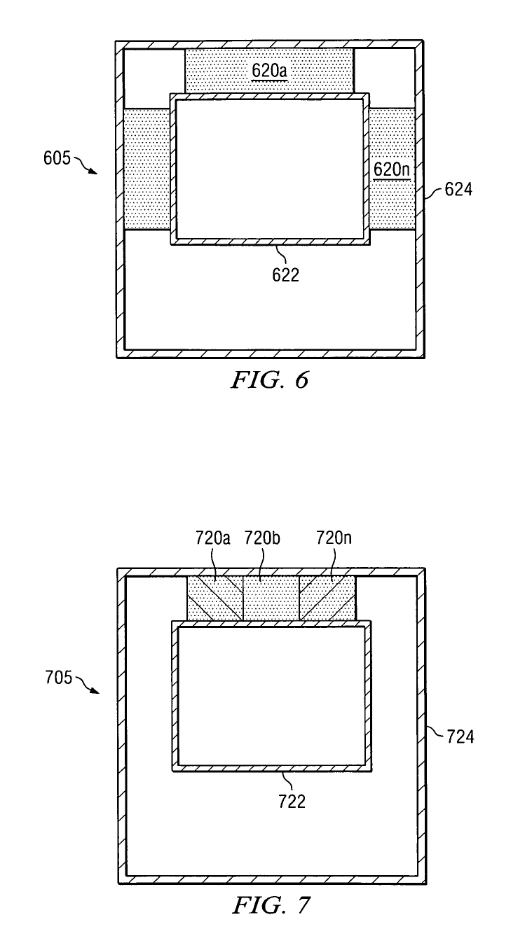

FIG. 6 is a cross-sectional view of an ONU 605 in which phase change material 620a, 620b, . . . , 620n is in contact with the top and two sides of the electronics enclosure 622. The phase change material 620a, 620b, . . . , 620n may also be in contact with the bottom and the other two sides of the electronics enclosure 622. In sum, the phase change material 620a, 620b, . . . , 620n may contact any portion of portions of the electronics enclosure 622 that is exposed to external temperature variations that influence the temperature internal to the electronics enclosure 622. In addition, the phase change material 620a, 620b, . . . , 620n may take on any shape or thickness, and the phase change material may be layered. In fact, the phase change material may be formed into the shape of a heat sink to facilitate more effective cooling.

FIG. 7 is another embodiment of an ONU 705 in which multiple phase change materials 720a, 720b, . . . , 720n of different formulations contact an electronics enclosure 722. For example, phase change material 720a may have a different phase change formulation from phase change material 720b. Phase change material 720a, 720b, . . . , 720n may also be made of the same or similar formulations.

FIG. 8 is a cross-sectional view of an ONU 805 that includes (i) a thermal buffer 850 between the second enclosure 824 and the assembly of an electronics enclosure 822 and (ii) a phase change material 820. The thermal buffer 850 may include a first wall 850a, a second wall 850c, and a thermal buffer region 850b between the first wall 850a and the second wall 850c. Alternatively, the second enclosure 824 may include a first wall 850a, a second wall 850c, and a thermal buffer region 850b between the first wall 850a and the second wall 850c. The thermal buffer region 850b may be filled with air, Styrofoam™, rubber, or any other material or combination of materials to insulate the electronics enclosure 822 and the PCM 820 from external heat sources.

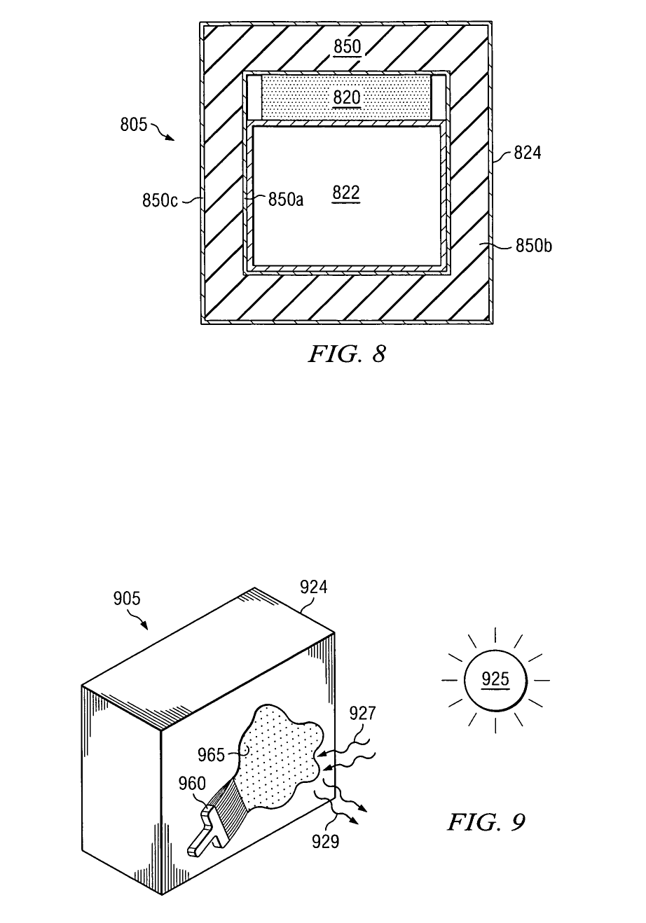

FIG. 9 is a perspective view of an ONU 905 whose exterior surface of the second enclosure 924 is exposed to the sun's 925 radiation, which includes radiation in the near infrared spectrum 927. A paint 965 may be applied with an applicator 960 to the exterior surface of the second enclosure 924 to reflect the sun's 925 radiation. Additives, such as “cool pigments,” may be added to the paint 965 to reflect radiation in the near infrared spectrum 929. Cool pigments have been developed at Lawrence Livermore Laboratories of California, U.S.A. to reflect radiation in the near infrared spectrum while allowing the paint to keep its same given color. Thus, pedestals 924 may be painted with almond or off-white paint as desired by the subscribers. Tests have shown that almond or off-white paint with cool pigments can reflect 66% of the radiation in the near infrared spectrum.

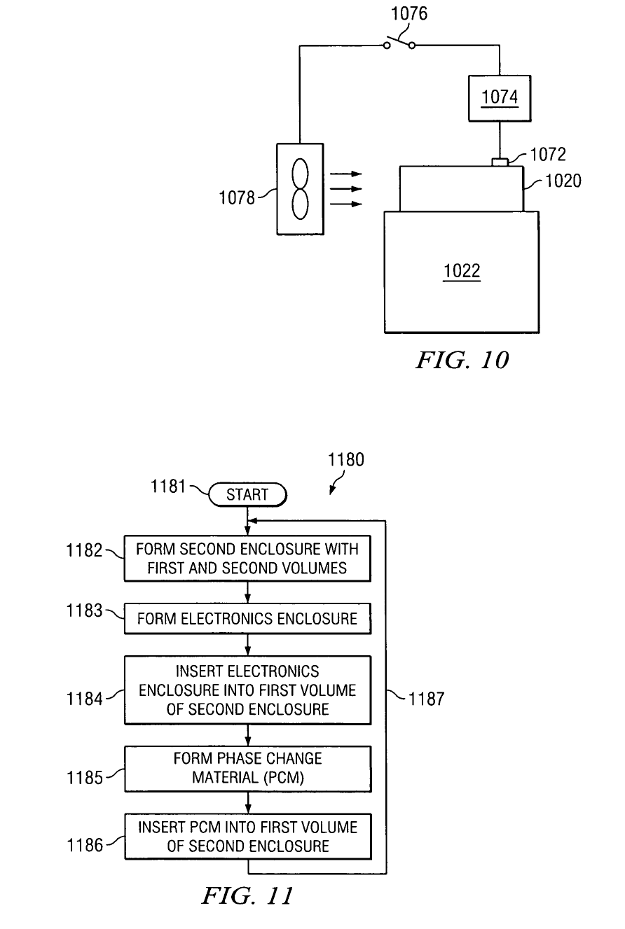

FIG. 10 is a block diagram of a bi-modal embodiment in which both active and passive cooling techniques are used. A sensor 1072 may be used to monitor a rate at which the phase change material 1020 is cooling. A different sensor (not shown) may also monitor the temperature within an electronics enclosure 1022. A processor 1074 connected to the sensor 1072 may determine whether or not the phase change material 1020 has reached its capacity or has a cooling rate that is within its capacity. The processor 1074 may also determine whether the temperature within the electronics enclosure 1022 warrants assistance of a fan 1078. If the processor 1074 determines that an active cooling mechanism such as the fan 1078 is necessary, then the processor 1074 activates a switch 1076 to operate the active cooling mechanism 1078. The pedestal may include holes to facilitate the transfer of heat out via forced hot air or convection of the pedestal. When the processor 1074 determines that the active cooling mechanism 1078 is no longer necessary, then it deactivates the switch 1076 to disable the active cooling mechanism 1078.

FIG. 11 is a flow chart of a process for manufacturing an ONU or ONT 1180. In step 1181, the manufacturing process starts. In step 1182, a second enclosure or pedestal is formed with at least a first volume and a second volume in heat transfer association with each other. The first volume is formed to receive an electronics enclosure, and the second volume is formed to receive a phase change material. In step 1183, an electronics enclosure is formed. In step 1184, the electronics enclosure is inserted into the first volume of the second enclosure. In step 1185, a phase change material is formed to fit into the second volume of the second enclosure. Finally, in step 1186, the phase change material is inserted into the second volume of the second enclosure. The manufacturing process 1180 returns 1187 to step 1182 to construct another ONU or ONT.

While this invention has been particularly shown and described with references to preferred embodiments thereof, it will be understood by those skilled in the art that. various changes in form and details may be made therein without departing from the scope of the invention encompassed by the appended claims.

For example, in the manufacturing process of FIG. 11, the ONU or the ONT may be constructed in any manner known by those having ordinary skill in the art. For example, the second enclosure or pedestal may be constructed by screwing or fastening together panels or by employing a molding process. Also, the electronics enclosure may be formed as part of the second enclosure. In the manufacturing process, the phase change material may be placed in a package, such as a metallic pouch, or the first volume may be filled with the phase change material and sealed.

The phase change material may be exposed to an external environment, or it may be positioned in an enclosure.

The phase change material according to embodiments of the present invention may be used in other applications. For example, the phase change material may be used in shipping electronics, pharmaceuticals, or any other temperature sensitive products.

The passive cooling system of the present invention may be combined with other passive or active cooling systems. Other passive cooling systems include the use of heat sinks. Active cooling systems include the use of muffin fans, refrigeration, compressors or any system that uses electrical, mechanical, or chemical energy to provide cooling. An active cooling mechanism may operate when a sensor senses a temperature beyond what the passive cooling system is capable of handling. The active cooling system may cause the phase change material to revert from its second state back to its first state.

What is claimed is:

1. An apparatus for cooling an electronics environment, comprising:
an electronics enclosure configured to receive electronics; and
a phase change material disposed in association with a location defined for the electronics, the electronics enclosure adapted to be deployed in an environment causing the electronics and the phase change material (i) to experience periods of heating undesirable for the electronics during which the phase change material changes at least partially from a first state to a second state in a manner absorbing heat to maintain temperature at a desirable level for the electronics and (ii) to experience periods of cooling allowing the phase change material to revert at least partially back to the first state for future heat absorption.

2. The apparatus according to claim 1 wherein the electronics enclosure is a sealed enclosure and the electronics are disposed in the sealed enclosure.

3. The apparatus according to claim 1 wherein the phase change material is in contact with one or more portions of the electronics enclosure that are exposed to external temperature variations that influence temperature internal to the electronics enclosure.

4. The apparatus according to claim 1 further comprising:
a second enclosure, the electronics enclosure being disposed inside the second enclosure.

5. The apparatus according to claim 4 wherein the phase change material is disposed between an exterior surface of the electronics enclosure and an interior surface of the second enclosure.

6. The apparatus according to claim 4 further comprising:
a paint applied to the second enclosure, the paint including a paint additive that reflects a near infrared spectrum to reduce external solar loading to the electronics enclosure.

7. The apparatus according to claim 4 wherein the second enclosure comprises a thermal buffer.

8. The apparatus according to claim 1 wherein the phase change material is thermally exposed to a thermally cooler body than the phase change material in the second state.

9. The apparatus according to claim 8 wherein the thermally cooler body is the night sky exhibiting a black sky dome effect.

10. The apparatus according to claim 8 wherein the thermally cooler body is a surface of a building that cools faster than the phase change material.

11. The apparatus according to claim 1 wherein the phase change material comprises multiple phase change materials of different formulations.

12. The apparatus according to claim 1 further comprising:
a sensor monitoring air temperature within the electronics enclosure selectively causing an active cooling mechanism to operate.

13. A method for cooling an electronics environment, comprising:
positioning a phase change material in association with a location defined for electronics in an environment causing the electronics and the phase change material (i) to experience periods of heating undesirable for the electronics during which the phase change material changes at least partially from a first state to a second state in a manner absorbing heat to maintain temperature at a desirable level for the electronics and (ii) to experience periods of cooling allowing the phase change material to revert at least partially back to the first state for future heat absorption.

14. The apparatus according to claim 13 wherein the electronics enclosure is a sealed enclosure and the electronics are disposed in the sealed enclosure.

15. The method according to claim 13 wherein positioning the phase change material comprises positioning the phase change material in an electronics enclosure in a location predominantly thermally exposing the phase change material to external temperature variations that influence temperature internal to the electronics enclosure.

16. The method according to claim 13 further comprising positioning the electronics enclosure inside a second enclosure.

17. The method according to claim 16 wherein positioning the phase change material comprises positioning the phase change material between an exterior surface of the electronics enclosure and an interior surface of the second enclosure.

18. The method according to claim 16 further comprising:
applying a paint to the second enclosure that includes a paint additive, the paint additive reflecting a near infrared spectrum to reduce external solar loading to the electronics enclosure.

19. The method according to claim 16 wherein the second enclosure comprises a thermal buffer.

20. The method according to claim 13 wherein positioning the phase change material comprises thermally exposing the phase change material to a thermally cooler body than the phase change material in the second state.

21. The method according to claim 20 wherein the thermally cooler body is the night sky exhibiting a black sky dome effect.

22. The method according to claim 20 wherein the thermally cooler body is a surface of a building that cools faster than the phase change material.

23. The method according to claim 13 wherein the phase change material comprises multiple phase change materials of different formulations.

24. The method according to claim 13 further comprising:
monitoring air temperature within the electronics enclosure; and
causing an active cooling mechanism to operate in response to the monitoring.

25. A method of manufacturing an electronics enclosure, comprising:
forming an electronics enclosure with a first volume defined to receive electronics and a second volume defined to receive a phase change material, the first volume being in heat transfer association with the second volume; and
positioning the phase change material in the second volume.
